(19) United States
(12) Patent Application Publication
(10) Pub. No.: US 2005/0128019 A1
(43) Pub. Date: Jun. 16, 2005

(54) Refresh oscillator

(76) Inventor: Ja Seung Gou, Goyangi-Shi (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/831,994

(22) Filed: Apr. 26, 2004

(30) Foreign Application Priority Data
Dec. 10, 2003 (KR) 2003-89321

(51) Int. Cl. H03B 1/00

(52) U.S. Cl. 331/185

(57) ABSTRACT

The present invention discloses a refresh oscillator including a biasing circuit for generating constant first and second biases by using current mirrors, regardless of variations of a power supply voltage, a start-up circuit for stabilizing the initial operation of the biasing circuit by applying a predetermined level of potential to the biasing circuit, and an oscillator for generating a constant period of refresh signals according to the first and second biases. The refresh oscillator can improve operation reliability by generating a constant period of signals, regardless of variations of the power supply voltage.

### BACKGROUND OF THE INVENTION

1. Field of the Invention

The present invention relates to a refresh oscillator, and more particularly to a refresh oscillator which can always generate a constant period of signals regardless of variations of a power supply voltage during a self refresh operation for periodically performing a refresh operation in a DRAM.

2. Description of the Background Art

A self refresh oscillator is used to guarantee a self refresh operation period for repeating a refresh operation in a DRAM after a predetermined time. The self refresh oscillator generates a constant period of signals and determines a self refresh period using the signals.

FIG. 1 is a circuit diagram illustrating a conventional refresh oscillator, including a biasing circuit 10 for determining levels of first and second biases BIAS1 and BIAS2 by controlling resistance of resisters R11 to R15 between diode-coupled PMOS transistor P11 and NMOS transistor N11 by using fuses F11 to F13, and an oscillator 20 for controlling an oscillation period by using the first and second biases BIAS1 and BIAS2.

In the biasing circuit 10, the first PMOS transistor P11 driven according to a potential of a first node Q11 is diode-coupled between a power supply terminal VDD and the first node Q11, the plurality of resisters R11 to R15 are coupled in series between the first node Q11 and a second node Q12, and the first NMOS transistor N11 driven according to a potential of the second node Q12 is coupled between the second node Q12 and a ground terminal VSS. Each fuse F11 to F13 are coupled in parallel to the respective resisters R12 to R14, and thus the resistance between the first and second nodes Q11 and Q12 are determined by cutting the fuses F11 to F13. The potential of the first node Q11 becomes the first bias BIAS1 and the potential of the second node Q12 becomes the second bias BIAS2.

In addition, the oscillator 20 includes a plurality of inverters I11 to I15. PMOS transistors P12 to P16 driven according to the first bias BIAS1 are coupled between the power supply terminal VDD and pull-up devices of the inverters I11 to I15, respectively, and NMOS transistors N12 to N16 driven according to the second bias BIAS2 are coupled between pull-down devices of the inverters I11 to 115 and the ground terminal VSS, respectively. The oscillator 20 adjusts an oscillation period by controlling a current necessary for the operations of the inverters I11 to 115 by using the PMOS transistors P12 to P16 and the NMOS transistors N12 to N16. On the other hand, in the inverters I11 to 115 composing the oscillator 20, the output of the preceding inverter become the input of the succeeding inverter, and the output of the final inverter becomes both the output of the oscillator 20 and the input of the first inverter.

In the conventional refresh oscillator, operation points of the PMOS transistors P12 to P16 and the NMOS transistors N12 to N16 operated as loads of each inverter I11 to I15 are determined according to the levels of the first and second biases BIAS1 and BIAS2. The first and second biases BIAS1 and BIAS2 are determined according to drain voltages of the diode-coupled PMOS transistor P11 and NMOS transistor N11. When the resistance is controlled by cutting the fuses F11 to F13 to operate the PMOS transistor P11 and the NMOS transistor N11 in a linear region, the levels of the first and second biases BIAS1 and BIAS2 are controlled. Therefore, the current flowing through the PMOS transistors P12 to P16 and the NMOS transistors N12 to N16 is controlled, to change the oscillation period. That is, the oscillation period can be trimmed by cutting the fuses F11 to F13 coupled in parallel to the resisters R12 to R14.

However, when the conventional refresh oscillator is operated in a low power of about 1.6V, such as a DDR2 or low power DDR, voltage margins excluding operation voltages of the inverters I11 to I15 are not greater than threshold voltages of the PMOS transistors P12 to P16 and the NMOS transistors N12 to N16. As a result, the PMOS transistors P12 to P16 and the NMOS transistors N12 to N16 are operated in a cut off region, and thus the existing current is very different from a value of the linear region, to considerably change the oscillation period.

In addition, the biasing circuit 10 determines the levels of the first and second biases BIAS1 and BIAS2 by controlling the resisters R11 to R15 between the diode-coupled PMOS transistor P11 and NMOS transistor N11 by using the fuses F11 to F13. In case that a level of the power supply voltage VDD is varied, namely, levels of sources in PMOS transistors P12 to P16 are varied, due to an operation requiring large power consumption, the levels of the biases are also changed. The resulting levels of the biases change the oscillation period, which causes problems in the operation. Currents flowing to the NMOS transistors and the PMOS transistors are increased or decreased exponentially in accordance with the variation of bias levels due to the variation of power supply voltage, because the PMOS transistors P12 to P16 and the NMOS transistors N12 to N16 operate linearly. Therefore, the oscillation period varies rapidly.

### SUMMARY OF THE INVENTION

The present invention is achieved to solve the above problems. Accordingly, it is a primary object of the present invention to provide a refresh oscillator which can always generate a constant period of signals by supplying constant biases to an oscillator by applying a constant current by using current mirrors, regardless of power supply voltage variation.

Another object of the present invention is to provide a refresh oscillator which can always generate a constant period of signals even in a low power supply voltage.

In accordance with an embodiment of the present invention, there is provided a refresh oscillator, comprising: a biasing circuit for generating constant first and second biases regardless of variations of a power supply voltage; and an oscillator for generating refresh signals having a constant period according to the first and second biases.

In accordance with another embodiment of the present invention, there is provided a refresh oscillator, comprising: a biasing circuit for generating constant first and second biases regardless of variations of a power supply voltage; a start-up circuit for stabilizing the initial operation of the biasing circuit by applying a predetermined voltage to the biasing circuit; and an oscillator for generating a constant period of refresh signals according to the first and second biases.

### BRIEF DESCRIPTION OF THE DRAWINGS

The present invention will become better understood with reference to the accompanying drawings which are given only by way of illustration and thus are not limitative of the present invention, wherein:

FIG. 1 is a circuit diagram illustrating a conventional refresh oscillator; and

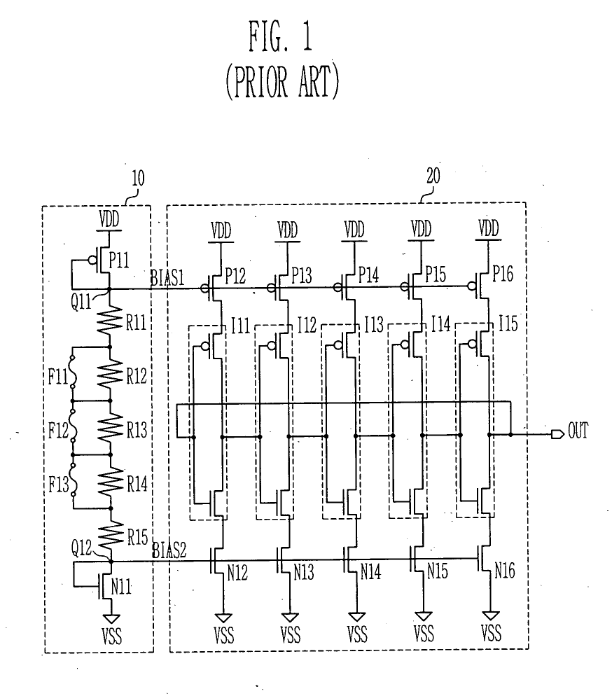

FIG. 2 is a circuit diagram illustrating a refresh oscillator in accordance with a preferred embodiment of the present invention.

### DETAILED DESCRIPTION OF THE PREFERRED EMBODIMENTS

A refresh oscillator in accordance with a preferred embodiment of the present invention will now be described in detail with reference to the accompanying drawings.

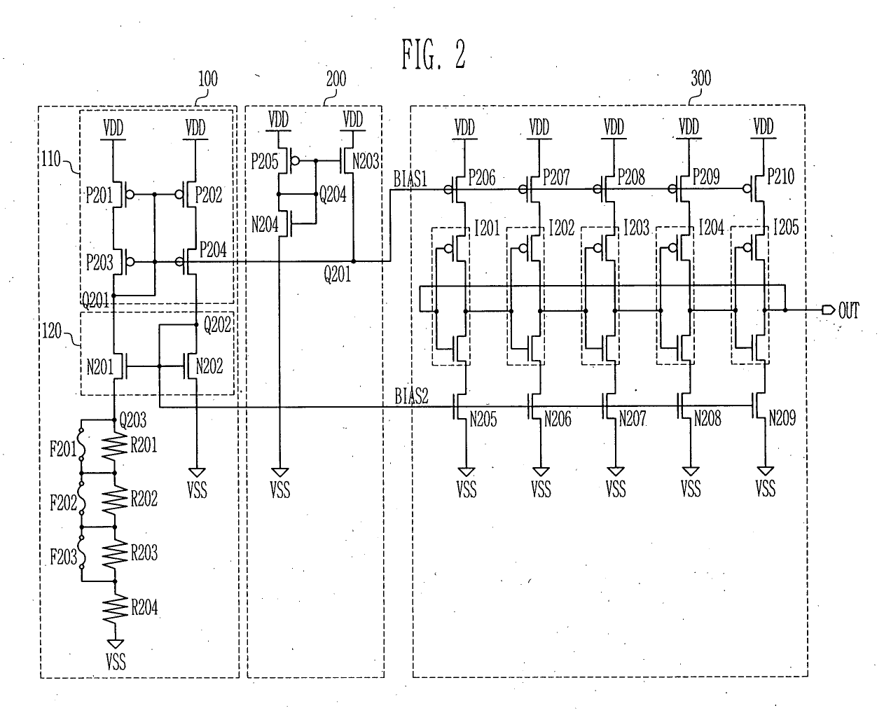

FIG. 2 is a circuit diagram illustrating the refresh oscillator in accordance with the present invention.

A biasing circuit 100 includes first and second current mirrors 110 and 120, and determines levels of first and second biases BIAS1 and BIAS2. The first current mirror 110 includes four diode connected PMOS transistors P201 to P204, therefore, the four PMOS transistors P201 to 204 are operated in saturation region if a voltage between a drain and a source of each PMOS transistor P201 to P204 is higher than a threshold voltage.

The second current mirror 120 includes first and second NMOS transistors N201 and N202 that are operated in a saturation region. Accordingly, the first and second biases BIAS1 and BIASI2 maintain a constant level regardless of variations of a power supply voltage VDD. The first and third PMOS transistors P201 and P203 are coupled in series between a power supply terminal VDD and a first node Q201, and the second and fourth PMOS transistors P202 and P204 are coupled in series between the power supply terminal VDD and a second node Q202. Gates of the first to fourth PMOS transistors P201 to P204 are connected to the first node Q201. The first to fourth PMOS transistors P201 to P204 are driven according to a potential of the first node Q201. The first NMOS transistor N201 is coupled between the first node Q201 and a third node Q203, and the second NMOS transistor N202 is coupled between the second node Q202 and a ground terminal VSS. The first and second NMOS transistors N201 and N202 are driven according to a potential of the second node Q202. A plurality of resisters R201 to R204 are coupled in series between the third node Q203 and the ground terminal VSS, and each fuse F201 to F203 are coupled in parallel to the respective resisters R201 to R203, respectively. The potential of the first node Q201 is controlled by adjusting the resistance of the resisters R201 to R204 by cutting the fuses F201 to F203. In other words, the first bias BIAS1 level and the second bias BIAS2 level can be controlled by adjusting resistance between the third node Q203 and the ground terminal Vss. Here, the potential of the first node Q201 becomes the first bias BIAS1, and the potential of the second node Q202 becomes the second bias BIAS2.

A start-up circuit 200 stabilizes the initial operation of the biasing circuit 100, and includes a fifth PMOS transistor P205 coupled between the power supply terminal VDD and a fourth node Q204, a fourth NMOS transistor N204 coupled between the fourth node Q204 and the ground terminal VSS, and a third NMOS transistor N203 coupled between the power supply terminal VDD and the first node Q201. Here, the fifth PMOS transistor P205, the third NMOS transistor N203 and the fourth NMOS transistor N204 are driven according to a potential of the fourth node Q204.

An oscillator 300 includes an odd number of inverters 1201 to 1205 driven according to the first and second biases BIAS1 and BIAS2, for outputting consecutive pulses. A plurality of PMOS transistors P206 to P210 driven according to the first bias BIAS1 are coupled between the power supply terminal VDD and pull-up devices of the inverters I201 to I205, respectively, and a plurality of NMOS transistors N205 to N209 driven according to the second bias BIAS2 are coupled between pull-down devices of the inverters I201 to I205 and the ground terminal VSS, respectively. The oscillator 300 controls a current necessary for the operations of the inverters 1201 to 1205 by using the PMOS transistors P206 to P210 and the NMOS transistors N205 to N209. On the other hand, in the inverters 1201 to 1205 composing the oscillator 300, the output of the preceding inverter become the input of the succeeding inverter, and the output of the final inverter becomes both the output of the oscillator 300 and the input of the first inverter.

In accordance with the present invention, the refresh oscillator generates the first and second biases BIAS1 and BIAS2 by using the first and second current mirrors 110 and 120 of the biasing circuit 100. The first and second PMOS transistors P201 and P202 and the third and fourth PMOS transistors P203 and P204 which compose the first current mirror 110 are driven in pairs according to the potential of the first node Q201. That is, the two PMOS transistors form one pair, to output the constant first bias BIAS1 regardless of variations of the power supply voltage VDD. In addition, the first and second NMOS transistors N201 and N202 composing the second current mirror 120 are driven in a pair according to the potential of the second node Q202. On the other hand, the first bias BIAS1 can be controlled by adjusting the values of the plurality of resisters R201 to R204 by cutting the fuses F201 to F203.

In regard to variations of the power supply voltage VDD, the levels of the first and second biases BIAS1 and BIAS2 are determined to operate the PMOS transistors P201 to P204 and the NMOS transistors N201 and N202 in the saturation region. The inverters 1201 to 1205 of the oscillator 300 are operated by the same current by the first and second biases BIAS1 and BIAS2, regardless of variations of the power supply voltage VDD. The gate levels are biased through the current mirrors in order to flow constant currents to the PMOS transistors P206 to P210 and the NMOS transistors N205 to N209, therefore, an output driving current and an inversion speed of each inverter become constant, and a constant period can be obtained.

Because the first and second biases BIAS1 and BIAS2 are operated not in the linear region but the saturation region, the refresh oscillator can be operated in a power supply level over a sum of threshold voltages of the PMOS transistors P206 to P210 and the NMOS transistors N205 to N209, about 1.4V of low power supply voltage VDD.

On the other hand, the operation of the start-up circuit 200 for stabilizing the initial operation of the biasing circuit 100 will now be explained. When the power supply voltage VDD is low and the first bias BIAS1 is approximate to 0V, if the potential of the fourth node Q204 is low, the fifth PMOS transistor P205 is turned on to rise the potential of the fourth node Q204. When the potential of the fourth node Q204 rises, the third and fourth NMOS transistors N203 and N204 are turned on to rise the first bias BIAS2. However, because the fourth NMOS transistor N204 is turned on, the potential of the fourth node Q204 falls. Therefore, the fifth PMOS transistor P205 is turned on and the third NMOS transistor N203 is turned off, to drop the first bias BIAS1. It is thus possible for the first bias BIAS1 to maintain a constant potential. Such a constant potential turns on the first to fourth PMOS transistors P201 to P204 of the first current mirror 110.

As discussed earlier, in accordance with the present invention, the refresh oscillator generates constant biases by using the current mirrors, regardless of variations of the power supply voltage, and supplies the constant biases to the oscillator by using the start-up circuit for stabilizing the biasing circuit, thereby outputting a constant period of signals. As a result, the refresh oscillator can be applied to the design of all DRAM circuits requiring the self refresh operation.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

1. A refresh oscillator, comprising:
a biasing circuit for generating constant first and second biases regardless of variations of a power supply voltage; and
an oscillator for generating refresh signals having a constant period according to the first and second biases.

2. The refresh oscillator of claim 1, further comprising a start-up circuit for stabilizing the initial operation of the biasing circuit by applying a predetermined voltage to the biasing circuit.

3. The refresh oscillator of claim 1, wherein the biasing circuit comprises first and second current mirrors for applying a predetermined current to first and second nodes, a potential of the first node becoming the first bias, a potential of the second node becoming the second bias.

4. The refresh oscillator of claim 3, wherein the first current mirror comprises:
first and third PMOS transistors coupled in series between a power supply terminal and the first node; and
second and fourth PMOS transistors coupled in series between the power supply terminal and the second node, the first to fourth PMOS transistors being driven according to the potential of the first node.

5. The refresh oscillator of claim 3, wherein the second current mirror comprises:
a first NMOS transistor coupled between the first node and a third node; and
a second NMOS transistor coupled between the second node and a ground terminal, the first and second NMOS transistors being driven according to the potential of the second node.

6. The refresh oscillator of claim 3, wherein the biasing circuit further comprises:
a plurality of resisters coupled in series between the second mirror and the ground terminal; and
a plurality of fuses each of which coupled in parallel to the respective resisters, the first bias being controlled by adjusting resistance of the resisters by cutting the fuses.

7. The refresh oscillator of claim 2, wherein the start-up circuit comprises:
a third NMOS transistor coupled between a power supply terminal and a first node;
a fifth PMOS transistor coupled between the power supply terminal and a fourth node; and
a fourth NMOS transistor coupled between the fourth node and a ground terminal, the third and fourth NMOS transistors and the fifth PMOS transistor being driven according to a potential of the fourth node.

8. The refresh oscillator of claim 1, wherein the oscillator comprises:
a plurality of inverters, each of which has a pull-up device and a pull-down device, wherein the inverters are connected in series between an input terminal of the oscillator and an output terminal thereof, the output terminal being connected to the input terminal;
a plurality of PMOS transistors coupled between a power supply terminal and pull-up devices of the inverters and driven according to the first bias; and
a plurality of NMOS transistors coupled between pull-down devices of the inverters and the ground terminal and driven according to the second bias.

9. A refresh oscillator, comprising:
a biasing circuit for generating constant first and second biases regardless of variations of a power supply voltage;
a start-up circuit for stabilizing the initial operation of the biasing circuit by applying a predetermined voltage to the biasing circuit; and
an oscillator for generating a constant period of refresh signals according to the first and second biases.

10. The refresh oscillator of claim 9, wherein the biasing circuit comprises first and second current mirrors for applying a predetermined current to first and second nodes, a potential of the first node becoming the first bias, a potential of the second node becoming the second bias.

11. The refresh oscillator of claim 10, wherein the first current mirror comprises:
first and third PMOS transistors coupled in series between a power supply terminal and the first node; and
second and fourth PMOS transistors coupled in series between the power supply terminal and the second node, the first to fourth PMOS transistors being driven according to the potential of the first node.

12. The refresh oscillator of claim 10, wherein the second current mirror comprises:
a first NMOS transistor coupled between the first node and a third node; and
a second NMOS transistor coupled between the second node and a ground terminal, the first and second NMOS transistors being driven according to the potential of the second node.

13. The refresh oscillator of claim 10, wherein the biasing circuit further comprises:
a plurality of resisters coupled in series between the second mirror and the ground terminal; and
a plurality of fuses each of which coupled in parallel to the respective resisters, the first bias being controlled by adjusting resistance of the resisters by cutting the fuses.

14. The refresh oscillator of claim 9, wherein the start-up circuit comprises:
a third NMOS transistor coupled between a power supply terminal and a first node;
a fifth PMOS transistor coupled between the power supply terminal and a fourth node; and
a fourth NMOS transistor coupled between the fourth node and a ground terminal, the third and fourth NMOS transistors and the fifth PMOS transistor being driven according to a potential of the fourth node.

15. The refresh oscillator of claim 9, wherein the oscillator comprises:
a plurality of inverters, each of which has a pull-up device and a pull-down device, wherein the inverters are connected in series between an input terminal of the oscillator and an output terminal thereof, the output terminal being connected to the input terminal;
a plurality of PMOS transistors coupled between a power supply terminal and pull-up devices of the inverters and driven according to the first bias; and
a plurality of NMOS transistors coupled between pull-down devices of the inverters and the ground terminal and driven according to the second bias.
